(19) United States
(12) Patent Application Publication
(10) Pub. No.: US 2002/0090834 A1
(43) Pub. Date: Jul. 11, 2002

(54) Method for depositing silicon dioxide on a substrate surface using hexamethyldisiloxane (HMDSO) as a precursor gas

(76) Inventors: Wei William Lee, Tainan (TW); Changming Jin, Plano, TX (US); Kelly J. Taylor, Allen, TX (US)

Correspondence Address: TEXAS INSTRUMENTS INCORPORATED, P O BOX 655474, M/S 3999, DALLAS, TX, 75265

(21) Appl. No.: 09/999,015

(22) Filed: Oct. 25, 2001

Related U.S. Application Data
(60) Provisional application No. 60/256,426, filed on Dec. 18, 2000.

(51) Int. Cl. H01L 21/469; H01L 21/31

(52) U.S. Cl. 438/787; 438/789; 438/790

(57) ABSTRACT

An IC includes one or more gaps (18) substantially filled with silicon dioxide (30). The silicon dioxide (30) is deposited into the gaps (18) in response to the reaction of hexamethyldisiloxane (HMDSO) (26) with ozone (28) during a plasma-enhanced CVD (PECVD) process. The IC may be fabricated by inserting a substrate into a chamber. HMDSO (26) and ozone (28) are introduced into the chamber. The HMDSO (26) reacts with the ozone (28) to produce silicon dioxide (30), which is then deposited on the surface (10) of the substrate.

### BACKGROUND OF THE INVENTION

Filling relatively narrow gaps on the surface of a substrate with silicon dioxide is often an important step in the fabrication of an integrated circuit (IC). Historically, such gap-filling has been accomplished by traditional chemical vapor deposition (CVD) techniques using tetraethoxysilane (TEOS) and ozone as precursor gases. However, there are several limitations associated with such techniques.

One such limitation is the incomplete gap-filling that often results from CVD using TEOS as a precursor gas. To function properly, many of the components of an IC have to be electrically isolated from each other, and an important step in the isolation process may be filling gaps that separate connectors and other devices with silicon dioxide. The failure to sufficiently fill such gaps may result in incomplete electircal isolation of IC components, adversely affecting the performance of those components and the overall performance of the IC.

Another limitation associated with previous techniques is the surface sensitivity of silicon dioxide deposited at low temperatures by CVD using TEOS and ozone as precursor gases. Due to the thermal instability of many of the components of an IC, CVD at temperatures above approximately 500 degrees Celsius may be incompatible with certain back-end IC fabrication processes. Therefore, it is often necessary to deposit silicon dioxide at lower temperatures, despite the surface sensitivity problems that arise as a result. One approach to reducing surface sensitivity involves treating the substrate surface prior to CVD by, for example, placing a thin layer of oxide on the substrate surface or plasma-treating the substrate surface. However, this approach is disadvantageous in that it adds to the number of steps in the fabrication process.

Another limitation associated with previous techniques is that silicon dioxide deposited by CVD using TEOS as a precursor gas typically has a dielectric constant above approximately 4.1. As the scale of electronic devices has become smaller, it has become increasingly important to be able to isolate the components of an IC with silicon dioxide having a dielectric constant below approximately 4.1. Since silicon dioxide deposited by CVD using TEOS as a precursor gas typically has a dielectric constant above this range, previous techniques do not address this need.

Any one or more of these or other deficiencies have made previous techniques for depositing silicon dioxide inadequate for many IC fabrication needs.

### SUMMARY OF THE INVENTION

According to the present invention, disadvantages and problems associated with previous methods for depositing silicon dioxide on a substrate surface are substantially reduced or eliminated.

In accordance with one embodiment of the present invention, an IC includes one or more gaps substantially filled with silicon dioxide. The silicon dioxide is deposited into the gaps in response to the reaction of hexamethyldisiloxane (HMDSO) with ozone during a plasma-enhanced CVD (PECVD) process.

In accordance with another embodiment of the present invention, a method for depositing silicon dioxide on a surface of a substrate during fabrication of an IC includes inserting a substrate into a chamber. Ozone and HMDSO are introduced into the chamber. The HMDSO reacts with the ozone to produce silicon dioxide, which is then deposited on the surface of the substrate.

The present invention provides important technical advantages over previous methods for depositing silicon dioxide on a substrate surface. Unlike previous methods, PECVD using HMDSO as a precursor gas substantially fills relatively narrow, relatively high aspect ratio gaps with silicon dioxide, thereby improving electrical isolation of IC components and IC performance. For example, the present invention has been shown to substantially fill gaps having a width of approximately 0.28 micrometers and an aspect ratio of approximately 2.5. Another advantage of the present invention is that silicon dioxide deposited by PECVD using HMDSO as a precursor gas at temperatures below 500 degrees Celsius does not exhibit significant surface sensitivity, reducing or eliminating the need to treat the substrate surface prior to CVD. Another technical advantage of the present invention is that PECVD using HMDSO as a precursor gas may be used to deposit silicon dioxide having a dielectric constant below approximately 4.1, making it possible to electrically isolate the components of an IC with relatively low dielectric constant silicon dioxide.

One or more of these or other technical advantages make the present invention well suited for modern IC fabrication. Other technical advantages are readily apparent to those skilled in the art from the following figures, descriptions, and claims.

### BRIEF DESCRIPTION OF THE DRAWINGS

To provide a more complete understanding of the present invention and the features and advantages thereof, reference is made to the following description taken in conjunction with the accompanying drawings, in which:

FIGS. 1A-1C illustrate exemplary deposition of silicon dioxide on a substrate surface using HMDSO as a precursor gas; and

FIG. 2 illustrates an exemplary method of depositing silicon dioxide on a substrate using HMDSO as a precursor gas.

### DETAILED DESCRIPTION OF THE INVENTION

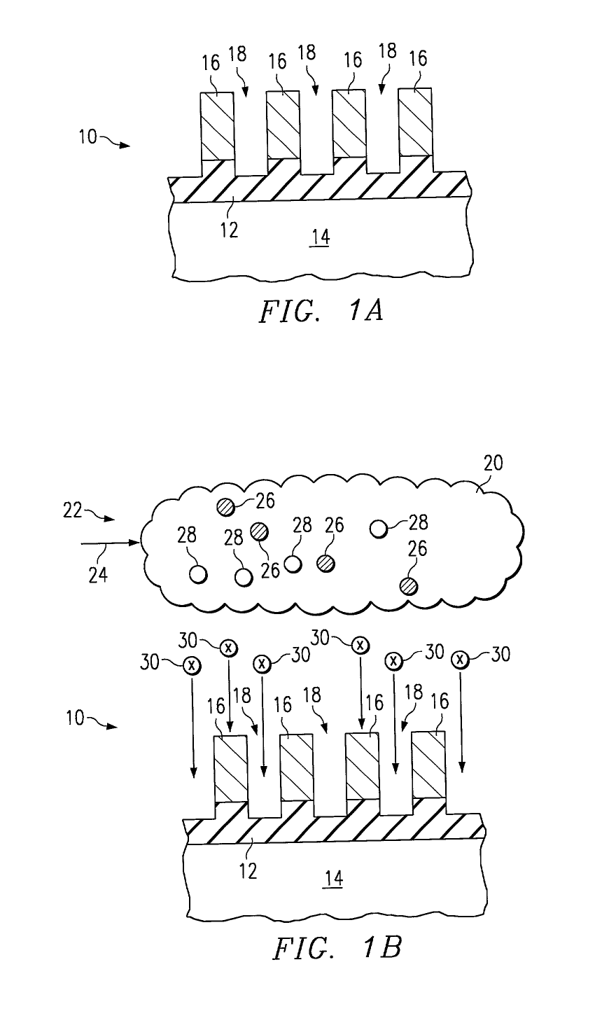

FIGS. 1A-1C illustrate exemplary deposition of silicon dioxide on a substrate surface 10 using HMDSO as a precursor gas. Referring to FIGURE 1A, a layer 12 of silicon dioxide has been grown on a layer of silicon 14 and patterned, and metal or other conductive connectors 16 separated by gaps 18 have been formed on the silicon dioxide layer 12, using traditional or other suitable fabrication techniques. In one embodiment, gaps 18 are relatively narrow, relatively high aspect ratio gaps 18, although substrate surface 10 may have any suitable gaps 18 without departing from the intended scope of the present invention. Although silicon 14, silicon dioxide layer 12, and conductive connectors 16 are primarily described, those skilled in the art will appreciate that the present invention is not limited to any particular substrate surface or IC component. The present invention encompasses deposition of silicon dioxide on any substrate surface or IC component, according to particular needs.

Referring to FIG. 1B, a suitable mixture 24 of HMDSO 26 and ozone 28 has been introduced into the area 22 adjacent to substrate surface 10 containing plasma 20, resulting in the transfer of energy from plasma 20 to HMDSO 26 and ozone 28. This transfer of energy in turn causes HMDSO 26 to react with ozone 28, resulting in the deposition of silicon dioxide 30 on substrate surface 10. Although mixture 24 is described, HMDSO 26 and ozone 28 may be introduced into plasma 20 sequentially, substantially simultaneously, or in any other suitable manner. Those skilled in the art will appreciate that the present invention is not limited to any particular PECVD technique.

Referring to FIG. 1C, according to the present invention, a layer of silicon dioxide 30 has been deposited on the substrate surface 10 to substantially fill gaps 18 separating connectors 16, resulting in substantial electrical isolation of connectors 16.

The present invention provides important technical advantages over previous methods for depositing silicon dioxide on a substrate surface. Unlike previous methods, PECVD using HMDSO 26 as a precursor gas substantially fills relatively narrow, relatively high aspect ratio gaps 18 with silicon dioxide 30, thereby improving electrical isolation of IC components and IC performance. Another advantage of the present invention is that silicon dioxide 30 deposited by PECVD using HMDSO 26 as a precursor gas at temperatures below 500 degrees Celsius does not exhibit significant surface sensitivity, reducing or eliminating the need to treat the substrate surface 10 prior to CVD. Another technical advantage of the present invention is that PECVD using HMDSO 26 as a precursor gas may be used to deposit silicon dioxide 30 having a dielectric constant below approximately 4.1, making it possible to isolate the components of an IC with relatively low dielectric constant silicon dioxide.

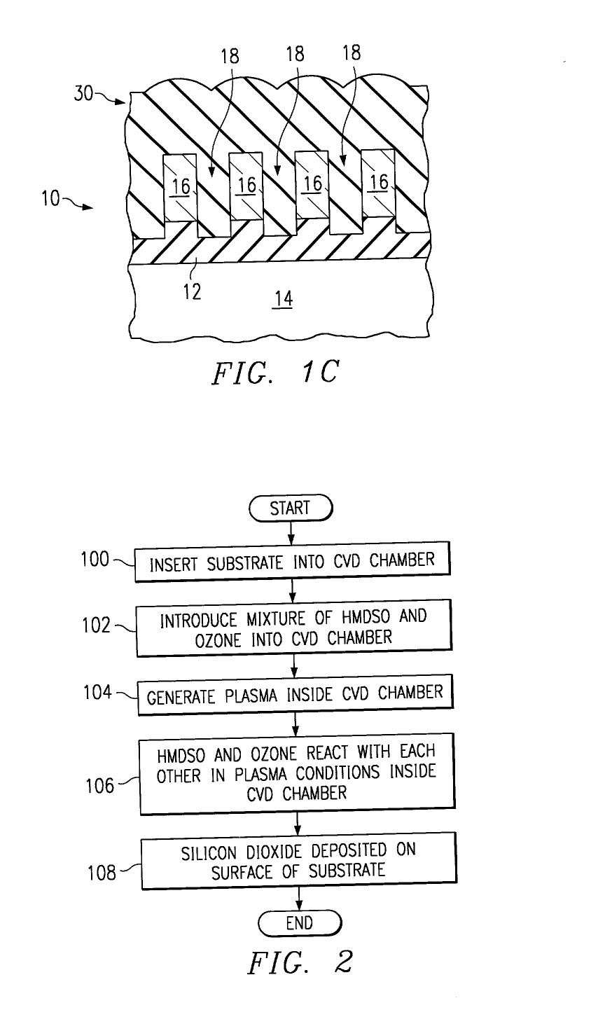

FIG. 2 illustrates an exemplary method of depositing silicon dioxide 30 on a substrate surface 10 using HMDSO 26 as a precursor gas. At step 100, a substrate at a stage in the IC fabrication process is inserted into a CVD chamber. At step 102, mixture 24 of HMDSO 26 and ozone 28 is introduced into the CVD chamber. At step 104, plasma 20 is generated inside the CVD chamber. As described above, HMDSO 26 and ozone 28 may be introduced sequentially, substantially simultaneously, or in any other suitable manner. At step 106, HMDSO 26 and ozone 28 react with each other in plasma conditions inside the CVD chamber, resulting in, at step 108, the deposition of silicon dioxide 30 on the subsrate surface 10.

Although the present invention has been described with one embodiment, a myriad of changes, variations, alterations, transformations and modifications may be suggested to one skilled in the art, and it is intended that the present invention encompasses such changes, variations, alterations, transformations, and modifications as fall within the spirit and scope of the appended claims.

What is claimed is:

1. A method for depositing silicon dioxide on a surface of a substrate during fabrication of an integrated circuit, comprising:
inserting the substrate into a chamber;
introducing ozone into the chamber;
introducing hexamethyldisiloxane (HMDSO) into the chamber;
reacting the HMDSO with the ozone to produce silicon dioxide; and
depositing the silicon dioxide on the surface of the substrate.

2. The method of claim 1, further comprising:
introducing a gas into the chamber in addition to the ozone and the HMDSO; and
applying a field to the gas, the ozone, and the HMDSO to generate a plasma, the HMDSO reacting with the ozone in the presence of the plasma.

3. The method of claim 1, wherein the substrate comprises one or more gaps, the silicon dioxide being deposited such that the gaps are substantially filled.

4. The method of claim 3, wherein the gaps are relatively narrow and have relatively high aspect ratios.

5. The method of claim 1, wherein the substrate comprises regions of conductive material separated by the gaps, the silicon dioxide being deposited such that at least two of the regions are electronically isolated from one another.

6. The method of claim 1, wherein depositing silicon dioxide occurs at a temperature of less than approximately 500 degrees Celsius.

7. The method of claim 1, wherein the silicon dioxide has a dielectric constant of less than approximately 4.1.

8. The method of claim 1, wherein the silcon dioxide exhibits less surface sensitivity than silicon dioxide deposited using tetraethoxysilane (TEOS) as a precursor gas.

9. An integrated circuit fabricated at least in part by:
inserting a substrate into a chamber;
introducing ozone into the chamber;
introducing hexamethyldisiloxane (HMDSO) into the chamber;
reacting the HMDSO with the ozone to produce silicon dioxide; and
depositing the silicon dioxide on a surface of the substrate.

10. The integrated circuit of claim 9, further fabricated by:
introducing a gas into the chamber in addition to the ozone and HMDSO; and
applying a field to the gas, the ozone, and the HMDSO to generate a plasma, the HMDSO reacting with the ozone in the presence of the plasma.

11. The integrated circuit of claim 9, wherein the substrate comprises one or more gaps, the silicon dioxide being deposited such that the gaps are substantially filled.

12. The integrated circuit of claim 11, wherein the gaps are relatively narrow and have relatively high aspect ratios.

13. The integrated circuit of claim 11, wherein the substrate comprises regions of conductive material separated by gaps, the silicon dioxide being deposited such that at least two of the regions are electrically isolated from one another.

14. The integrated circuit of claim 9, wherein depositing silicon dioxide occurs at a temperature of less than approximately 500 degrees Celsius.

15. The integrated circuit of claim 9, wherein the silicon dioxide has a dielectric constant of less than approximately 4.1.

16. The integrated circuit of claim 9, wherein the silcon dioxide exhibits less surface sensitivity than silicon dioxide deposited using tetraethoxysilane (TEOS) as a precursor gas.

17. An integrated circuit, comprising:
one or more gaps; and
silicon dioxide substantially filling the gaps, the silicon dioxide deposited into the gaps in response to reaction of hexamethyldisiloxane (HMDSO) with ozone during a plasma-enhanced chemical vapor deposition process.

18. The integrated circuit of claim 17, wherein the silicon dioxide is deposited at a temperature of less than approximately 500 degrees Celsius.

19. The integrated circuit of claim 17, wherein the silicon dioxide has a dielectric constant of less than approximately 4.1.

20. The integrated circuit of claim 17, wherein the silcon dioxide exhibits less surface sensitivity than silicon dioxide deposited using tetraethoxysilane (TEOS) as a precursor gas.
